(19) United States
(12) Patent Application Publication
(10) Pub. No.: US 2026/0113859 A1
(43) Pub. Date: Apr. 23, 2026

(54) BUOYANCY TRAY, SERVER, AND SERVER CLUSTER

(71) Applicant: SUZHOU METABRAIN INTELLIGENT TECHNOLOGY CO., LTD., Suzhou, Jiangsu (CN)

(72) Inventors: Hongming WANG, Suzhou, Jiangsu (CN); Daming WANG, Suzhou, Jiangsu (CN); Guangying XUE, Suzhou, Jiangsu (CN)

(21) Appl. No.: 19/153,598

(22) PCT Filed: Feb. 7, 2024
(86) PCT No.: PCT/CN2024/076537

§ 371 Date: Aug. 4, 2025

(30) Foreign Application Priority Data
Feb. 16, 2023 (CN) 202310123500.3

(51) Int. Cl. H05K 7/14; H05K 7/20

(52) U.S. Cl. CPC H05K 7/1485; H05K 7/20763

(57) ABSTRACT

A buoyancy tray, a server, and a server cluster are provided by the present application. In the present application, the buoyancy component is disposed on the tray body, when the tray body is located in the immersion coolant of the cabinet, buoyancy generated by the buoyancy component may assist maintenance personnel in pulling out the server from the cabinet directly through the handles on the tray body, thereby facilitating convenient and labor-saving operation, and improving the operating efficiency.

### CROSS-REFERENCE TO RELATED APPLICATION

The present application claims the priority of the Chinese Patent application filed on February 16^{th}, 2023 before the China National Intellectual Property Administration with the application number of 202310123500.3, and the title of “BUOYANCY TRAY, SERVER, AND SERVER CLUSTER”, which is incorporated herein in its entirety by reference.

### FIELD

The present application relates to the technical field of servers and, more particularly, to a buoyancy tray, a server, and a server cluster.

### BACKGROUND

Currently, in large-scale deployment liquid-cooling whole cabinets, servers are directly inserted into the cabinets fully filled with coolant. When configuration changes or maintenance are needed, the servers need to be completely pulled out from the cabinet and placed onto a maintenance workbench.

However, due to the substantial weight of the server, a mechanical lifting arm is needed to lift and transfer the server in a process of pulling out the entire server from the cabinet. On one hand, the operation time of the mechanical lifting arm is long, resulting in low operating efficiency, and violating a rapid operation/maintenance principle of data centers; and on the other hand, the mechanical lifting arm has relatively high requirements on skills of operators, the operators need to have dedicated training and to be selected, skill acquisition costs are increased.

### SUMMARY

A buoyancy tray, a server, and a server cluster are provided by an embodiment of the present application, to solve problems of low operating efficiency and increasing skill acquisition cost caused by employing a mechanical lifting arm for operation.

A buoyancy tray configured to place a server into a cabinet containing immersion coolant is provided by an embodiment of the present application. The buoyancy tray includes a tray body, buoyancy air holders, and air holder filling blocks;
a tray body, wherein a server slot configured to load the server is disposed at one end of the tray body, handles are disposed at two sides of the one end of the tray body, and two sides of the tray body are provided with first recessed slide tracks matched with first protruding slide tracks inside the cabinet; and
a buoyancy component, wherein the buoyancy component is disposed on the tray body, and an inside of the buoyancy component is a closed hollow structure, and the buoyancy component is configured to provide buoyancy for the tray body.

In some embodiments, the buoyancy component includes buoyancy air holders, the buoyancy air holders are disposed at two sides of the tray body, insides of the buoyancy air holders are hollow structures and each of the first recessed slide tracks is disposed at one end of each of the buoyancy air holders away from the tray body.

In some embodiments, the buoyancy component includes air holder filling blocks, and the air holder filling blocks are disposed at a bottom of the server slot.

In some embodiments, the air holder filling blocks are distributed in a spaced array in the server slot.

In some embodiments, each of the buoyancy air holders is provided with scale marks along a length direction.

In some embodiments, the scale marks are uniformly distributed at intervals along the length direction.

In some embodiments, latch slots are disposed at preset intervals on each of the first protruding slide tracks, and each of the first recessed slide tracks is provided with latches matched with the latch slots.

In some embodiments, each of the first protruding slide tracks is formed by a plurality of protruding slide blocks that are distributed at intervals.

In some embodiments, the latch slots are disposed on the protruding slide blocks.

In some embodiments, each of the first recessed slide tracks is also provided with a fixed shaft and a pull rod, and each of the handles of the tray body is provided with a pull ring;
each of the latches is sleeved on the fixed shaft, one end of the pull ring is connected to one end of the pull rod in each of the first recessed slide tracks, the other end of the pull rod is provided with a beveled clamping block, a clamping slot is disposed at one end of each of the latches close to the pull rod, the beveled clamping block is movably clamped into the clamping slot, a clamping tooth matched with the latch slot is disposed at one end of the each of the latches away from the pull rod, and an elastic component is disposed between the clamping tooth and each of the first recessed slide tracks;
in response to the pull ring being not pulled, the clamping tooth is embedded into the latch slot under an action of an elastic force of the elastic component; and
in response to the pull ring being pulled, the beveled clamping block of the pull rod is driven to move towards the handle, the latch rotates around the fixed shaft, one end of the latch provided with the clamping slot moves away from the tray body, the clamping tooth moves towards the tray body, the elastic component is compressed, and the clamping tooth is separated from the latch slot.

In some embodiments, the fixed shaft is located at one end within each of the first recessed slide tracks away from the handle.

In some embodiments, the elastic component is a spring or an elastic sheet.

In some embodiments, a bottom of a chassis base and a top cover are both hollowed structures.

In some embodiments, the server includes a rack formed by a chassis base and a top cover, handles are disposed at two sides of one end of the chassis base, and air holder filling blocks are disposed at the other end of the chassis base.

In some embodiments, each of two sides of the chassis base is provided with a second protruding slide track, and second recessed slide tracks matched with the second protruding slide tracks are disposed in the server slot.

In some embodiments, locking nuts are disposed at two sides of the one end of the tray body, and locking screws matched with the locking nuts are disposed at two sides of one end of the chassis base.

In some embodiments, the air holder filling blocks are distributed in a spaced array at the other end of the chassis base.

In some embodiments, a bottom of the tray body is a hollowed structure.

In some embodiments, the air holder filling blocks are cube air holder filling blocks.

In some embodiments, the buoyancy air holders are cuboid buoyancy air holders.

A server is further provided by some embodiments of the present application, which includes the buoyancy tray according to any one of embodiments stated above.

A server cluster is further provided by some embodiments of the present application, which includes the cabinet containing immersion coolant and the server stated above.

A server cluster is further provided by some embodiments of the present application, which includes the cooling system stated above.

Embodiments of present application have the following advantages: the buoyancy component is disposed on the tray body, when the tray body is located in the immersion coolant of the cabinet, buoyancy generated by the buoyancy component may assist maintenance personnel in pulling out the server from the cabinet directly through the handles on the tray body without the assistance of a mechanical lifting arm, thereby facilitating convenient and labor-saving operation, and improving the operating efficiency; and moreover, the maintenance personnel require no special skill training, skill acquisition costs are reduced.

### BRIEF DESCRIPTION OF THE DRAWINGS

FIG. 1 is a schematic structural diagram of a buoyancy tray according to an embodiment of the present application;

FIG. 2 is an exploded schematic structural diagram of a buoyancy tray according to an embodiment of the present application;

FIG. 3 is a schematic structural diagram of a tray body according to an embodiment of the present application;

FIG. 4 is a first schematic structural diagram of a buoyancy tray inserted into a cabinet according to an embodiment of the present application;

FIG. 5 is a second schematic structural diagram of a buoyancy tray inserted into a cabinet according to an embodiment of the present application;

FIG. 6 is a schematic structural diagram of a buoyancy air holder according to an embodiment of the present application;

FIG. 7 is a schematic structural diagram of another buoyancy air holder according to an embodiment of the present application;

FIG. 8 is a schematic structural diagram of a server according to an embodiment of the present application;

FIG. 9 is a first schematic structural diagram of server installation according to an embodiment of the present application; and

FIG. 10 is a second schematic structural diagram of server installation according to an embodiment of the present application.

### DESCRIPTION OF REFERENCE NUMERALS IN THE DRAWINGS

100—Buoyancy tray, 110—tray body, 111—first recessed slide track, 112—second recessed slide track, 113—pull ring, 114—pull rod, 115—latch, 116—clamping slot, 117—clamping tooth, 118—elastic component; 119—beveled clamping block, 120—buoyancy component, 121—air holder filling block, 122—buoyancy air holder, 123—scale mark, 200—server, 210—chassis base, 211—second protruding slide track, 212—locking screw, 220—top cover, 300—cabinet, 310—protruding slide block, and 311—latch slot.

### DETAILED DESCRIPTION

In order to make the above purpose, characteristics, and advantages of the present application more apparent and understood, the present application is further described in detail below in combination with the drawings and embodiments.

Firstly, in large-scale deployment liquid-cooling whole cabinets at present, servers are directly inserted into the cabinets fully filled with coolant.

Secondly, mounting racks at two sides of the cabinet are each provided with a slide track, and the server is inserted into the cabinet under the guidance of the slide tracks.

Thirdly, in order to save coolant in the cabinet, filling blocks may be usually installed at spatial positions of the cabinet for the traditional server, and are typically made of solid bakelite.

Fourthly, when configuration changes or maintenance are needed, the server needs to be completely pulled out from the cabinet and placed onto a maintenance workbench. Due to a heavy weight of a chassis, a mechanical lifting arm is needed to lift and transfer the server.

The existing design has defects as follows.

The filling blocks mentioned in the third point and solid bakelite may bring about additional weight, which is unfavorable for unplugging the server for maintenance.

For the fourth point stated above: (1) even minor configuration changes/maintenance operations require the assistance of the mechanical lifting arm; (2) when a large number of servers need to be transferred and maintained rapidly, it is impractical to equip a sufficient number of mechanical lifting arms for lifting; and (3) the mechanical lifting arm has relatively high requirements on skills of operators, and improper handling may result in personal/property safety accidents. (4) The operation of the mechanical lifting arm is longtime-consuming, violating a rapid operation/maintenance principle of data centers. (5) The server removed by the mechanical lifting arm needs to be placed on a special placement workbench with a liquid collector, a transfer path is long, and the placement workbench may occupy a valuable space of a machine room.

Based on this, a buoyancy tray, a server, and a server cluster are provided by an embodiment of the present application. In an aspect, a buoyancy component is disposed on a tray body, and when the tray body is located in immersion coolant of a cabinet, buoyancy generated by the buoyancy component may assist maintenance personnel in pulling out the server from the cabinet directly through handles on the tray body, thereby facilitating convenient and labor-saving operation, improving the operating efficiency.

In another aspect, when no buoyancy tray is used in the related art to assist in plugging/unplugging the server, the server needs to be completely pulled out from the cabinet when the entire server needs to be replaced, and the server needs to be maintained (for example, elements such as a memory, a central processing unit (CPU), and the like in the server are maintained or replaced), the operation is complex, and the operating efficiency is low; and moreover, the immersion coolant on the server may drop outside the cabinet, causing waste of the immersion coolant. In the embodiment of the present application, first recessed slide tracks at two sides of the buoyancy tray are provided with latches, first protruding slide tracks on the cabinet are provided with latch slots corresponding to the latches, and the buoyancy tray and the server may be controlled to be suspended in the cabinet after being completely or partially pulled out from the immersion coolant through the cooperation of the latches and the latch slots. When the entire server needs to be replaced, the buoyancy tray and the server may be controlled to be suspended, after the coolant on the buoyancy tray and the server completely drops into the cabinet, the buoyancy tray and the entire server are pulled out from the cabinet, and the waste of the immersion coolant dropping outside the cabinet is avoided; and when elements in the server need to be maintained or replaced, the entire server does not need to be pulled out from the cabinet, and the elements in the server may be maintained or replaced directly only by pulling out the server from the immersion coolant and suspending the server in the cabinet, thereby facilitating easier operation, improving the operating efficiency, and further avoiding the waste of the immersion coolant caused by the outflow of the immersion coolant, at the same time. In addition, when the elements in a plurality of servers need to be maintained or replaced, the plurality of servers may be simultaneously pulled out from the immersion coolant first and suspended in the cabinet, and after the immersion coolant on the servers drains completely, the elements in the plurality of servers are maintained or replaced, thereby implementing batch operation on the servers, saving time, improving the operating efficiency without operating the servers one by one.

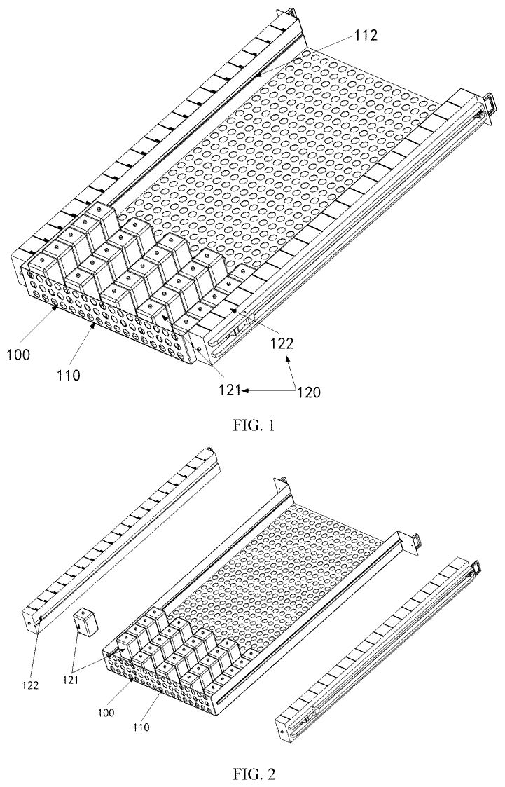

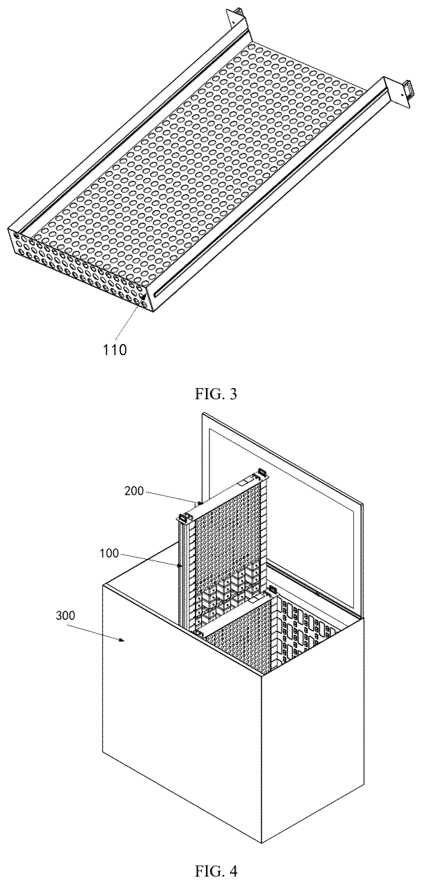

Referring to FIG. 1, which shows a schematic structural diagram of a buoyancy tray according to an embodiment of the present application. Referring to FIG. 2, which shows an exploded schematic structural diagram of a buoyancy tray according to an embodiment of the present application. Referring to FIG. 3, which shows a schematic structural diagram of a tray body according to an embodiment of the present application. A server 200 tray is configured to place a server 200 into a cabinet 300 containing immersion coolant, and the server 200 tray includes a tray body 110 and a buoyancy component 120.

A server slot configured to load the server 200 is disposed at one end of the tray body 110, handles are disposed at two sides of the one end of the tray body 110, and two sides of the tray body 110 are provided with first recessed slide tracks 111 matched with first protruding slide tracks inside the cabinet 300.

The buoyancy component 120 is disposed on the tray body 110, and an inside of the buoyancy component 120 is a closed hollow structure, and the buoyancy component is configured to provide buoyancy for the tray body 110.

The inside of the buoyancy component 120 is the closed hollow structure, the closed hollow structure is configured to hold gas such as air or another safety gas that is configured to provide buoyancy for the tray body 110.

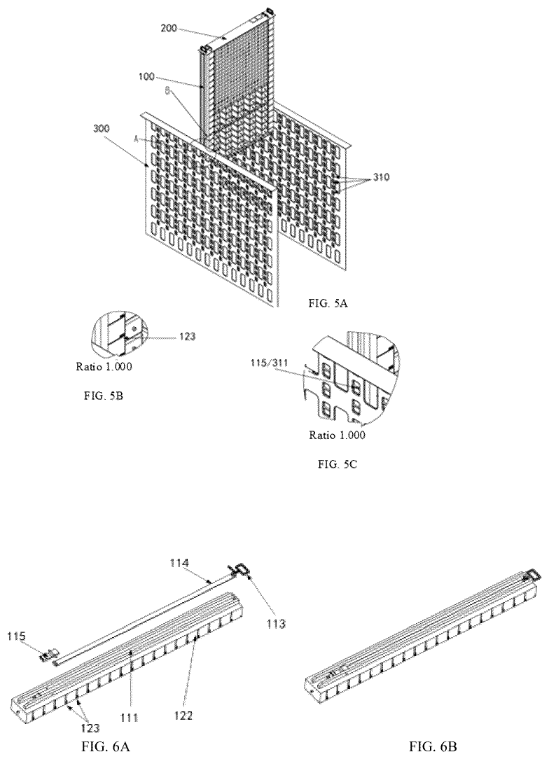

Specifically, the server 200 is loaded in the server slot of the tray body 110, then the tray body 110 is inserted into the cabinet 300 containing the immersion coolant, and the first recessed slide tracks 111 of the tray body 110 are inserted along the first protruding slide tracks in the cabinet 300, to submerge the server 200 in the immersion coolant in the cabinet 300. Referring to FIG. 4, which shows a first schematic structural diagram of a buoyancy tray inserted into a cabinet 300 according to an embodiment of the present application. Referring to FIG. 5, which shows a second schematic structural diagram of a buoyancy tray inserted into a cabinet 300 according to an embodiment of the present application. Through that the first recessed slide tracks 111 engage with the first protruding slide tracks, the buoyancy tray 100 may be inserted into the cabinet 300.

A buoyancy component 120 is disposed on a tray body 110, for example, may be disposed at the bottom and/or two sides of the tray body 110. Specifically, the buoyancy component may be disposed according to actual requirements. The position of the buoyancy component 120 on the tray body 110 is not limited in the present application.

The buoyancy component 120 is disposed on the tray body 110, since an inside of the buoyancy component 120 is hollow, the buoyancy component 120 is mainly configured to generate buoyancy, to reduce a weight of the tray body 110 and the server 200 in the immersion coolant, thereby enabling the maintenance personnel to pull out the tray body 110 and the server 200 from the cabinet 300 through handles on the tray body 110, without the assistance of a mechanical lifting arm.

In the embodiment of the present application, the buoyancy component is disposed on the tray body 110, the buoyancy generated by the buoyancy component 120 assists the maintenance personnel in pulling out the server 200 from the cabinet 300 directly through the handles on the tray body 110 without the assistance of the mechanical lifting arm, thereby facilitating convenient and labor-saving operation, and improving the operating efficiency; and moreover, the maintenance personnel requires no special skill training, skill acquisition costs are reduced.

Furthermore, the buoyancy component 120 is disposed on the tray body 110, which may increase a height of the immersion coolant in the cabinet 300, thereby saving the immersion coolant in the cabinet 300.

Based on the foregoing embodiment, a variant embodiment of the aforementioned embodiment is provided. It needs to be stated that for brief description, only difference between the variant embodiment and the aforementioned embodiment is described below.

In some embodiments of the present application, the buoyancy component includes buoyancy air holders 122, wherein the buoyancy air holders 122 are disposed at two sides of the buoyancy body 110, and a first recessed slide track 111 is disposed at one end of each of the buoyancy air holders 122 away from the tray body 110.

The first recessed slide tracks 111 may be disposed at two sides of the tray body 110, and when two sides of the tray body 110 are each provided with the buoyancy air holder 122, each of the first recessed slide tracks 111 is disposed at one end of each of the buoyancy air holders 122 away from the tray body 110, thereby facilitating the plugging/unplugging of the tray body 110 into/from the cabinet 300 through the cooperation of the first recessed slide tracks 111 and the first protruding slide tracks.

Specifically, the buoyancy air holders 122 are disposed at two sides of the tray body 110, and since the inside of each buoyancy air holder 122 is hollow, the buoyancy air holders 122 are mainly configured to provide the buoyancy, thereby enabling the maintenance personnel to pull out the tray body 110 and the server 200 from the cabinet 300 through the handles on the tray body 110 without the assistance of the mechanical lifting arm.

In some embodiments of the present application, the buoyancy component includes air holder filling blocks 121, and the air holder filling blocks 121 are disposed at a bottom of the server slot.

Specifically, the air holder filling blocks 121 are disposed at the bottom of the server slot of the tray body 110, and since the inside of each air holder filling block 121 is hollow, the air holder filling blocks 121 are configured to provide buoyancy, thereby enabling the maintenance personnel to pull out the tray body 110 and the server 200 from the cabinet 300 through the handles on the tray body 110 without the assistance of the mechanical lifting arm.

The buoyancy air holders 122 and the air holder filling blocks 121 are simultaneously installed on the tray body, the buoyancy generated by the buoyancy air holders 122 is primarily, the buoyancy generated by the air holder filling blocks 12 is supplementary, and the generated buoyancy enables the maintenance personnel to pull out the server 200 from the cabinet 300 directly through the handles on the tray body 110, thereby facilitating convenient and labor-saving operation, and improving the operating efficiency.

In some embodiments of the present application, the air holder filling blocks 121 are distributed in a spaced array in the server slot. Specifically, the air holder filling blocks 121 are distributed in an array in the server slot, and clearances are formed among the air holder filling blocks 121, facilitating the flow of the immersion coolant. The quantity of the air holder filling blocks 121 may be set according to a volume and weight of the server 200, which is not limited in the present embodiment of the present application.

In the foregoing embodiment, the air holder filling blocks 121 are distributed in an array in the server slot, and the buoyancy generated by the air holder filling blocks 121 is configured to assist the maintenance personnel in pulling out the server 200 from the cabinet 300 directly through the handles on the tray body 110 without the assistance of the mechanical lifting arm, thereby facilitating convenient and labor-saving operation, and improving the operating efficiency; and moreover, the maintenance personnel requires no special skill training, skill acquisition costs are reduced. Furthermore, the server 200 is provided with the air holder filling blocks 121, the height of the immersion coolant in the cabinet 300 may be increased, thereby the immersion coolant in the cabinet 300 is saved.

In some embodiments of the present application, each of the buoyancy air holders 122 is provided with scale marks 123 along a length direction. Specifically, each of the buoyancy air holders 122 is provided with the scale marks 123 along the length direction, whereby an insertion depth of the buoyancy tray 100 into the cabinet 300 may be controlled as required according to a length of the server 200.

In some embodiments of the present application, the scale marks 123 are uniformly distributed at intervals along the length direction. Specifically, the scale marks 123 are uniformly distributed at intervals, for example, a scale mark may be set every 50 mm (which is not limited to 50 mm, and may be set according to actual requirements), thereby facilitating controlling the plugging/unplugging of the buoyancy tray 100 by the maintenance personnel.

In some embodiments of the present application, latch slots 311 are disposed at preset intervals on each of the first protruding slide tracks, and each of the first recessed slide tracks 111 is provided with latches 115 matched with the latch slots 311.

Specifically, the latch slots 311 are disposed at preset intervals on the first protruding slide tracks, and the first recessed slide tracks 111 are provided with the latches 115 matched with the latch slots 311, thus in a process of inserting the buoyancy tray 100 into the cabinet 300, operation/maintenance heights of different servers 200 in different lengths may be satisfied by means of the cooperation of the latches 115 and the latch slots 311 with the assistance of the scale marks 123, the server may be suspended at different operation/maintenance heights, and elements at different heights in the server 200 may be maintained or replaced without pulling out the entire server 200 from the cabinet, thereby avoiding time and labor waste; and moreover, the coolant is naturally recycled into the cabinet 300 during the suspension of the server, thereby avoiding the dropping waste of the coolant.

In some embodiments of the present application, each of the first protruding slide tracks is formed by a plurality of protruding slide blocks 310 that are distributed at intervals. Specifically, a plurality of protruding slide blocks 310 that are distributed at intervals are disposed in a height direction in the cabinet 300, and through the plurality of protruding slide blocks 310 that are distributed at intervals, the first protruding slide track are formed.

In some embodiments of the present application, the latch slots 311 are disposed on the protruding slide blocks 310. The latch slots 311 are distributed at a preset distance.

In some embodiments of the present application, each of the first recessed slide tracks 111 is also provided with a fixed shaft and a pull rod 114, and each of the handles of the tray body 110 is provided with a pull ring 113.

Each of the latches 115 is sleeved on the fixed shaft, one end of the pull ring 113 is connected to one end of the pull rod 114 in each of the first recessed slide tracks 111, the other end of the pull rod 114 is provided with a beveled clamping block 119, a clamping slot 116 is disposed at one end of each of the latches 115 close to the pull rod 114, the beveled clamping block 119 is movably clamped into the clamping slot 116, a clamping tooth 117 matched with the latch slot is disposed at one end of the latch 115 away from the pull rod 114, and an elastic component 118 is disposed between the clamping tooth 117 and each of the first recessed slide tracks 111.

In response to the pull ring 113 being not pulled, the clamping tooth 117 is embedded into the latch slot under an action of an elastic force of the elastic component 118.

In response to the pull ring 113 being pulled, the beveled clamping block 119 of the pull rod 114 is driven to move towards the handle, the latch 115 rotates around the fixed shaft, one end of the latch 115 provided with the clamping slot 116 moves towards the tray body 110, the clamping tooth 117 moves away from the tray body 110, the elastic component 118 is compressed, and the clamping tooth 117 is separated from the latch slot 311.

Specifically, each of the latches 115 is sleeved on the fixed shaft, the pull ring 113 is disposed on the handle of the tray body 110, one end of the pull ring 113 is connected to one end of the pull rod 114 in each of the first recessed slide tracks 111, the other end of the pull rod 114 is provided with the beveled clamping block 119, one end of the latch 115 close to the pull rod 114 is provided with the clamping slot 116 matched with the beveled clamping block 119, the beveled clamping block 119 is movably clamped into the clamping slot 116, the clamping tooth 117 matched with the latch slot is disposed at one end of the latch 115 away from the pull rod 114, and the elastic component 118 is disposed between the clamping tooth 117 and the first recessed slide track 111. Referring to FIG. 6, which shows a schematic structural diagram of a buoyancy air holder according to an embodiment of the present application. FIG. 6(a) is an exploded schematic diagram of a buoyancy air holder 122. A side surface of the buoyancy air holder 122 is provided with scale marks 123, a latch 115 is sleeved on a fixed shaft, a pull ring 113 is disposed on a handle of a tray body 110, one end of the pull ring 113 is connected to one end of a pull rod 114 in a first recessed slide track 111. FIG. 6(b) is an assembly schematic diagram of a buoyancy air holder 122.

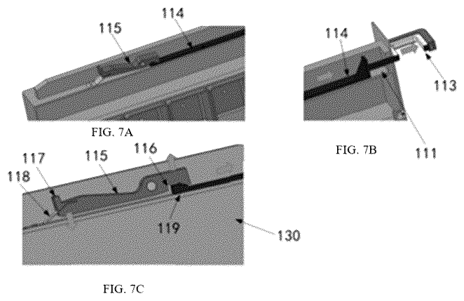

Referring to FIG. 7, which shows a schematic structural diagram of another buoyancy air holder according to an embodiment of the present application. A latch 115 is sleeved on a fixed shaft, a pull ring 113 is disposed on a handle of the tray body 110, one end of the pull ring 113 is connected to one end of a pull rod 114 in a first recessed slide track 111, the other end of the pull rod 114 is provided with a beveled clamping block 119, one end of the latch 115 close to the pull rod 114 is provided with a clamping slot 116 matched with the beveled clamping block 119, the beveled clamping block 119 is movably clamped into the clamping slot 116, a clamping tooth 117 matched with the latch slot is disposed at one end of the latch 115 away from the pull rod 114, and an elastic component 118 is disposed between the clamping tooth 117 and the first recessed slide track 111.

In response to the pull ring 113 being not pulled, the clamping tooth 117 is embedded into the latch slot under an action of an elastic force of the elastic component 118.

In response to the pull ring 113 being pulled, the beveled clamping block 119 of the pull rod 114 is driven to move towards the handle, a protruding part of the beveled clamping block 119 supports one end of the latch 115 provided with the clamping slot 116, the latch 115 rotates around the fixed shaft, one end of the latch 115 provided with the clamping slot 116 moves towards the tray body 110, the clamping tooth 117 moves away from the tray body 110, and the elastic component 118 is compressed to achieve the separation of the clamping tooth 117 from the latch slot 311, thereby controlling the unlocking of the latch 115 and the latch slot 311.

In response to the pull ring 113 being released, the clamping tooth 117 moves towards the tray body 110 under the action of the elastic force of the elastic component 118, thus it is achieved that the clamping tooth 117 is embedded into the latch slot 311; one end of the latch 115 provided with the clamping slot 116 may have a force facing a direction away from the tray body 110, under the combined action of an inclined surface of the clamping slot 116 and an inclined surface of the beveled clamping block 119, the beveled clamping block 119 of the pull rod 114 may move away from the handle and enter the clamping slot 116 of the latch 115, and one end of the latch 115 provided with the clamping slot 116 may move away from the tray body 110, thereby achieving the locking of the latch 115 and the latch slot 311.

Furthermore, a reset spring is added at a junction between one end of the pull ring 113 and one end of the pull rod 114, one end of the spring abuts against the inside of the first recessed slide track 111, the other end abuts against one end surface of the pull rod 114, when the pull ring 113 is strained, the pull rod 114 moves towards the handle, the reset spring is compressed, and when the pull ring 113 is released, the pull rod 114 moves away from the handle under the action of the elastic force of the reset spring.

In the foregoing embodiment, the locking of the latch 115 and the latch slot 311 is conducive to controlling an insertion depth of the buoyancy tray 100, a situation that the server 200 cannot be submerged in the coolant due to excessively large buoyancy of the air holder filling blocks 121 and the buoyancy air holders 122 may be prevented. At the same time, by controlling the locking and unlocking of the latches 115 and the latch slots 311, it is conducive to controlling the insertion depth of the buoyancy tray 100, enabling the buoyancy tray 100 and the server 200 to be suspended in the cabinet, and facilitating the maintenance operation by the maintenance personnel.

In some embodiments of the present application, the fixed shaft is located at one end within the first recessed slide track 111 away from the handle. Specifically, the fixed shaft is located at one end in the first recessed slide track 111 away from the handle, and the latch 115 that is sleeved on the fixed shaft is also located at one end within the first recessed slide track 111 away from the handle, thereby facilitating the control of the insertion depth of the buoyancy tray 100 through the latches 115.

It needs to be stated that the fixed shaft is disposed at one end in the first recessed slide track 111 away from the handle, and may also be disposed in other positions, such as a middle position of the first recessed slide track 111, which may be specifically set according to actual requirements, which is not limited in the embodiment of the present application.

In some embodiments of the present application, the elastic component 118 may be a spring or an elastic sheet. The clamping tooth 117 of the latch 115 is supported by the spring or the elastic sheet, thereby facilitating embedding the clamping tooth 117 into the latch slot 311.

In some embodiments of the present application, a bottom of a chassis base 210 and a top cover 220 are both hollowed structures, which facilitates the flow of the immersion coolant into the server 200.

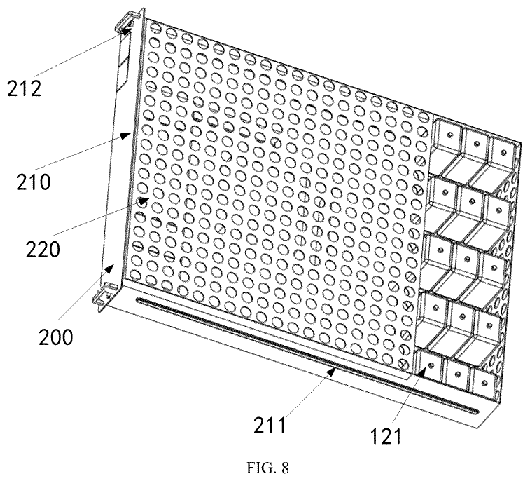

Referring to FIG. 8, which shows a schematic structural diagram of a server according to an embodiment of the present application. The server 200 includes a rack formed by a chassis base 210 and a top cover 220, handles are disposed at two sides of one end of the chassis base 210, and air holder filling blocks 121 are disposed at the other end of the chassis base 210.

Specifically, the air holder filling blocks 121 are disposed at the other end of the chassis base 210, and when the server 200 is submerged in immersion coolant, a weight of the server 200 may be reduced, and buoyancy generated by the air holder filling blocks 121 is configured to assist the maintenance personnel in pulling out the server 200 from the cabinet 300 directly through the handles on the tray body 110 without the assistance of a mechanical lifting arm, thereby facilitating convenient and labor-saving operation, and improving the operating efficiency; and moreover, the maintenance personnel requires no special skill training, skill acquisition costs are reduced. Furthermore, by that the server 200 is provided with the air holder filling blocks 121, a height of the immersion coolant in the cabinet 300 may be increased, thereby saving the immersion coolant in the cabinet 300.

In some embodiments of the present application, each of two sides of the chassis base 210 are provided with a second protruding slide track 211, and second recessed slide tracks 112 matched with the second protruding slide tracks 211 are disposed in the server slot. Therefore, the second recessed slide tracks 112 in the server slot match with the second protruding slide tracks 211 at two sides of the chassis base 210 of the server 200, enabling the insertion of the server 200 into the server slot of the buoyancy tray 100.

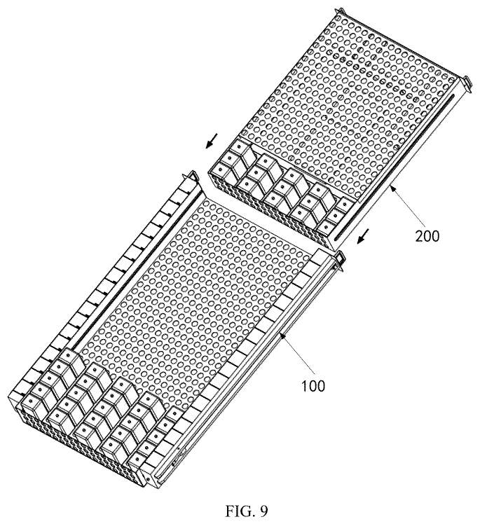

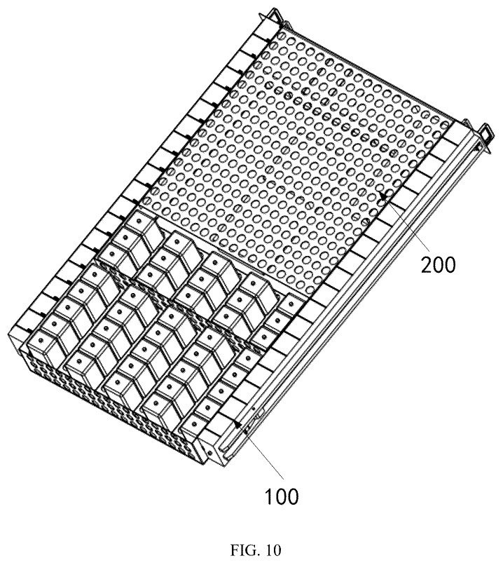

Referring to FIG. 9, which shows a first schematic structural diagram of server installation according to an embodiment of the present application. At this moment, a server 200 is not loaded on a buoyancy tray 100. Referring to FIG. 10, which shows a second schematic structural diagram of server 200 installation according to an embodiment of the present application. At this moment, the server 200 is loaded onto a buoyancy tray 100 through the cooperation of second protruding slide tracks 211 and second recessed slide tracks 112.

In some embodiments of the present application, locking nuts are disposed at two sides of the one end of the tray body 110, and locking screws 212 matched with the locking nuts are disposed at two sides of one end of the chassis base 210.

Specifically, the locking nuts are disposed at two sides of the one end of the tray body 110, and the locking screws 212 matched with the locking nuts are disposed at two sides of one end of the chassis base 210, thus when the server 200 is inserted into the server slot of the buoyancy tray 100, the server 200 may be fixed in the server slot of the buoyancy tray 100 through the cooperation of the locking screws 212 and the locking nuts, and the server 200 is prevented from being separated from the server slot in a process of inserting the buoyancy tray 100 into the cabinet 300.

In some embodiments of the present application, the air holder filling blocks 121 are distributed in a spaced array at the other end of the chassis base 210. Specifically, the air holder filling blocks 121 are distributed in an array at the other end of the chassis base 210, and clearances are formed among the air holder filling blocks 121, facilitating the flow of the immersion coolant. The quantity of the air holder filling blocks 121 may be set according to a volume and weight of the server 200, which is not limited in the present embodiment of the present application.

In the foregoing embodiment, the air holder filling blocks 121 are distributed in an array in the server 200, buoyancy generated by the air holder filling blocks 121 is configured to assist the maintenance personnel in pulling out the server 200 from the cabinet 300 directly through handles on the tray body 110 without the assistance of a mechanical lifting arm, thereby facilitating convenient and labor-saving operation, and improving the operating efficiency; and moreover, the maintenance personnel requires no special skill training, skill acquisition costs are reduced. Furthermore, the server 200 is provided with the air holder filling blocks 121, a height of the immersion coolant in the cabinet 300 may be increased, thereby the immersion coolant in the cabinet 300 is saved.

In some embodiments of the present application, a bottom of the tray body 110 is a hollowed structure, facilitating the flow of the immersion coolant in the server 200, and improving a liquid cooling effect.

In some embodiments of the present application, the air holder filling blocks 121 may be cube air holder filling blocks 121. Of course, the air holder filling blocks 121 may also be in other shapes, such as in a spherical shape and a cuboid shape. The shape of the air holder filling block may be specifically disposed according to actual requirements, and is not limited in the present embodiment of the present application.

In some embodiments of the present application, the buoyancy air holders 122 may be cuboid buoyancy air holders 122. Of course, the buoyancy air holder 122 may also be in other shapes, such as in a spherical shape and a cube shape. The shape of the buoyancy air holder may be specifically disposed according to actual requirements, and is not limited in the present embodiment of the present application.

In the foregoing embodiment, the structural solution of the server 200 in an immersion liquid-cooling cabinet 300 in the present application mainly includes a liquid-cooling cabinet 300 (abbreviated as a tank), a server 200, and a buoyancy bearing tray (a buoyancy tray 100).

Structural components of the server 200 mainly include a chassis base 210 and a top cover 220, and sealed hollow filling blocks (abbreviated as air holder filling blocks 121) for saving coolant. A housing of the server 200 is provided with handles, hand-tightening screws (locking screws 212), and protruding slide tracks (second protruding slide tracks 211) configured to be inserted into the buoyancy bearing tray.

The buoyancy bearing tray mainly includes a sheet-metal body, two buoyancy air holders 122, and air holder filling blocks 121. The sheet-metal body structure is in a tray form and is provided with through holes to facilitate the flow of coolant into the server 200; the handles are disposed at the upper end of the sheet-metal body structure to facilitate the operation/maintenance by operators; and the recessed slide tracks (the second recessed slide tracks 112) are disposed at two sides of the sheet-metal body structure and used for the server 200 to insert, and the locking nuts are disposed at two sides of the upper end and configured to lock the server 200; and a main body of each buoyancy air holder 122 is a closed hollow pot and is mainly configured to generate buoyancy, enabling the operation/maintenance personnel to pull out the server 200 without the assistance of a mechanical lifting arm. A latch 115, a pull rod 114, a pull ring 113, a reset spring, and an elastic sheet (an elastic component 118) are disposed at one side of each air holder.

The buoyancy air holder 122 on the server 200 has functions as follows: the air holder filling blocks 121 have two purposes, i.e., saving liquid, and generating the buoyancy; and the air holder filling blocks 121 are distributed in an array with clearances for flow of the liquid, and the quantity of the filling blocks may be customized according to the server 200 in different lengths.

The embodiments of the present application solve problems of the current liquid-cooling cabinet 300 and the server 200: firstly, the buoyancy bearing tray is labor-saving and assists in unplugging the server without the assistance of the mechanical lifting arm in most cases; secondly, the liquid filling blocks are changed from solid to be a closed hollow body, thereby achieving light weight and facilitating easier unplugging of the server; and the tank slide track is additionally provided with the clamping slot 116 that is matched with the latch 115 on the buoyancy bearing tray, and a scale mark is set every 50 mm (which is not limited to 50 mm, and the density may be increased according to actual requirements), thereby adapting to the operation/maintenance heights of a plurality of servers 200 in different lengths, enabling the server to be suspended at different operation/maintenance heights, and avoiding time and labor waste during the transfer of the server. When the server is suspended, the coolant is naturally recycled into the tank, thereby avoiding the dropping waste of the coolant.

A server 200 is further provided in an embodiment of the present application, which includes server 200 tray. The server 200 tray includes:
a tray body 110, wherein a server slot configured to load the server 200 is disposed at one end of the tray body 110, handles are disposed at two sides of the one end of the tray body 110, and two sides of the tray body 110 are provided with first recessed slide tracks 111 matched with first protruding slide tracks inside the cabinet; and
a buoyancy component 120, wherein the buoyancy component 120 is disposed on the tray body 110, and an inside of the buoyancy component 120 is a closed hollow structure, and the buoyancy component is configured to provide buoyancy for the tray body 110.

In some embodiments of the present application, the buoyancy component 120 includes buoyancy air holders 122, wherein the buoyancy air holders 122 are disposed at two sides of the tray body 110, an inside of each buoyancy air holder 122 is a closed hollow structure, and each of the first recessed slide tracks 111 is disposed at one end of each of the buoyancy air holders 122 away from the tray body 110.

In some embodiments of the present application, the buoyancy component 120 includes air holder filling blocks 121, the air holder filling blocks 121 are disposed at a bottom of the server slot, and the inside of each of the air holder filling blocks 121 is a closed hollow structure.

In some embodiments of the present application, the air holder filling blocks 121 are distributed in a spaced array in the server slot.

In some embodiments of the present application, each of the buoyancy air holders 122 is provided with scale marks 123 along a length direction.

In some embodiments of the present application, the scale marks 123 are uniformly distributed at intervals along the length direction.

In some embodiments of the present application, latch slots 311 are disposed at preset intervals on each of the first protruding slide tracks, and each of the first recessed slide tracks 111 is provided with latches 115 matched with the latch slots 311.

In some embodiments of the present application, each of the first protruding slide tracks is formed by a plurality of protruding slide blocks 310 that are distributed at intervals.

In some embodiments of the present application, the latch slots 311 are disposed on the protruding slide blocks 310.

In some embodiments of the present application, each of the first recessed slide tracks 111 is also provided with a fixed shaft and a pull rod 114, and each of the handles of the tray body 110 is provided with a pull ring 113.

Each of the latches 115 is sleeved on the fixed shaft, one end of the pull ring 113 is connected to one end of the pull rod 114 in each of the first recessed slide tracks 111, the other end of the pull rod 114 is provided with a beveled clamping block 119, a clamping slot 116 is disposed at one end of each of the latches 115 close to the pull rod 114, the beveled clamping block 119 is movably clamped into the clamping slot 116, a clamping tooth 117 matched with the latch slot is disposed at one end of each of the latches 115 away from the pull rod 114, and an elastic component 118 is disposed between the clamping tooth 117 and each of the first recessed slide tracks 111.

In response to the pull ring 113 being not pulled, the clamping tooth 117 is embedded into the latch slot under an action of an elastic force of the elastic component 118.

In response to the pull ring 113 being pulled, the beveled clamping block 119 of the pull rod 114 is driven to move towards the handle, the latch 115 rotates around the fixed shaft, one end of the latch 115 provided with the clamping slot 116 moves away from the tray body 110, the clamping tooth 117 moves towards the tray body 110, the elastic component 118 is compressed, and the clamping tooth 117 is separated from the latch slot 311.

In some embodiments of the present application, the fixed shaft is located at one end within each of the first recessed slide tracks 111 away from the handle.

In some embodiments of the present application, the elastic component 118 is a spring or an elastic sheet.

In some embodiments of the present application, a bottom of a chassis base 210 and a top cover 220 are both hollowed structures.

In some embodiments of the present application, the server 200 includes a rack formed by the chassis base 210 and the top cover 220, handles are disposed at two sides of one end of the chassis base 210, and air holder filling blocks 121 are disposed at the other end of the chassis base 210.

In some embodiments of the present application, each of two sides of the chassis base 210 is provided with a second protruding slide track 211, and second recessed slide tracks 112 matched with the second protruding slide tracks 211 are disposed in the server slot.

In some embodiments of the present application, locking nuts are disposed at two sides of the one end of the tray body 110, and locking screws 212 matched with the locking nuts are disposed at two sides of one end of a chassis base 210.

In some embodiments of the present application, the air holder filling blocks 121 are distributed in a spaced array at the other end of the chassis base 210.

In some embodiments of the present application, the bottom of the tray body 110 is a hollowed structure.

In some embodiments of the present application, the air holder filling blocks 121 are cube air holder filling blocks 121.

In some embodiments of the present application, the buoyancy air holders 122 are cuboid buoyancy air holders 122.

In the foregoing embodiment, the air holder filling blocks 121 are disposed at the bottom of the server slot of the tray body 110, and the buoyancy air holders 122 are disposed at two sides of the tray body 110, the buoyancy generated by the buoyancy air holders 122 and the air holder filling blocks 121 assists the maintenance personnel in pulling out the server 200 from the cabinet 300 directly through the handles on the tray body 110 without the assistance of the mechanical lifting arm, thereby facilitating convenient and labor-saving operation, and improving the operating efficiency; and moreover, the maintenance personnel requires no special skill training, skill acquisition costs are reduced.

Furthermore, the server 200 is provided with the air holder filling blocks 121, which may increase a height of the immersion coolant in the cabinet 300, thereby it is achieved that the immersion coolant in the cabinet 300 is saved.

For embodiments of the server 200, since the embodiments of the server 200 are basically similar to the embodiments of the buoyancy tray 100, the embodiments of the server are simply described. For relevant descriptions, the embodiments of the buoyancy tray 100 are referred to.

A server 200 cluster is further provided in an embodiment of the present application, which includes a cabinet 300 containing immersion coolant and a server 200, wherein the server 200 includes a tray body 110, and a server 200 tray includes:
the tray body 110, wherein a server slot configured to load the server 200 is disposed at one end of the tray body 110, and handles are disposed at two sides of the one end of the tray body 110;
air holder filling blocks 121, wherein the air holder filling blocks 121 are disposed at a bottom of the server slot, and an inside of each air holder filling block 121 is a closed hollow structure; and
buoyancy air holders 122, wherein the buoyancy air holders 122 are disposed at two sides of the tray body 110, an inside of each of the buoyancy air holders 122 is a closed hollow structure, and a first recessed slide track 111 matched with a first protruding slide track in the cabinet 300 is disposed at one end of each of the buoyancy air holders 122 away from the tray body 110.

In some embodiments of the present application, the air holder filling blocks 121 are distributed in a spaced array in the server slot.

In some embodiments of the present application, each of the buoyancy air holders 122 is provided with scale marks 123 along a length direction.

In some embodiments of the present application, the scale marks 123 are uniformly distributed at intervals along the length direction.

In some embodiments of the present application, latch slots 311 are disposed at preset intervals on each of the first protruding slide tracks, and each of the first recessed slide tracks 111 is provided with latches 115 matched with the latch slots 311.

In some embodiments of the present application, each of the first protruding slide tracks is formed by a plurality of protruding slide blocks 310 that are distributed at intervals.

In some embodiments of the present application, the latch slots 311 are disposed on the protruding slide blocks 310.

In some embodiments of the present application, each of the first recessed slide tracks 111 is also provided with a fixed shaft and a pull rod 114, and each of the handles of the tray body 110 is provided with a pull ring 113.

Each of the latches 115 is sleeved on the fixed shaft, one end of the pull ring 113 is connected to one end of the pull rod 114 in each of the first recessed slide tracks 111, the other end of the pull rod 114 is provided with a beveled clamping block 119, a clamping slot 116 is disposed at one end of each of the latches 115 close to the pull rod 114, the beveled clamping block 119 is movably clamped into the clamping slot 116, a clamping tooth 117 matched with the latch slot is disposed at one end of each of the latches 115 away from the pull rod 114, and an elastic component 118 is disposed between the clamping tooth 117 and each of the first recessed slide tracks 111.

In response to the pull ring 113 being not pulled, the clamping tooth 117 is embedded into the latch slot under an action of an elastic force of the elastic component 118.

In response to the pull ring 113 being pulled, the beveled clamping block 119 of the pull rod 114 is driven to move towards the handle, the latch 115 rotates around the fixed shaft, one end of the latch 115 with the clamping slot 116 moves away from the tray body 110, the clamping tooth 117 moves towards the tray body 110, the elastic component 118 is compressed, and the clamping tooth 117 is separated from the latch slot 311.

In some embodiments of the present application, the fixed shaft is located at one end within each of the first recessed slide tracks 111 away from the handle.

In some embodiments of the present application, the elastic component 118 is a spring or an elastic sheet.

In some embodiments of the present application, a bottom of a chassis base 210 and a top cover 220 are both hollowed structures.

In some embodiments of the present application, the server 200 includes a rack formed by the chassis base 210 and the top cover 220, handles are disposed at two sides of one end of the chassis base 210, and air holder filling blocks 121 are disposed at the other end of the chassis base 210.

In some embodiments of the present application, each of two sides of the chassis base 210 is provided with a second protruding slide track 211, and second recessed slide tracks 112 matched with the second protruding slide tracks 211 are disposed in the server slot.

In some embodiments of the present application, locking nuts are disposed at two sides of the one end of the tray body 110, and locking screws 212 matched with the locking nuts are disposed at two sides of one end of a chassis base 210.

In some embodiments of the present application, the air holder filling blocks 121 are distributed in a spaced array at the other end of the chassis base 210.

In some embodiments of the present application, a bottom of the tray body 110 is a hollowed structure.

In some embodiments of the present application, the air holder filling blocks 121 are cube air holder filling blocks 121.

In some embodiments of the present application, the buoyancy air holders 122 are cuboid buoyancy air holders 122.

In the foregoing embodiment, the air holder filling blocks 121 are disposed at the bottom of the server slot of the tray body 110, and the buoyancy air holders 122 are disposed at two sides of the tray body 110, the buoyancy generated by the buoyancy air holders 122 and the air holder filling blocks 121 assists the maintenance personnel in pulling out the server 200 from the cabinet 300 directly through the handles on the tray body 110 without the assistance of the mechanical lifting arm, thereby facilitating convenient and labor-saving operation, and improving the operating efficiency; and moreover, the maintenance personnel requires no special skill training, skill acquisition costs are reduced.

Furthermore, by that the server 200 is provided with the air holder filling blocks 121, a height of the immersion coolant in the cabinet 300 may be increased, thereby saving the immersion coolant in the cabinet 300.

For embodiments of the server 200 cluster, since the embodiments of the server 200 are basically similar to the embodiments of the buoyancy tray 100, the embodiments of the server cluster are simply described. For relevant descriptions, the embodiments of the buoyancy tray 100 are referred to.

It needs to be stated that terms used here such as “include”, “contain” or any other variations thereof are intended to cover a non-exclusive inclusion, so that a process, a method, an article, or an apparatus including a series of elements does not include only those elements but also other elements not expressly listed or also includes the intrinsic elements of the process, the method, the article, or the apparatus. Without further limitations, an element defined by the sentence “including an” do not exclude the presence of other same elements in the process, the method, the article the or apparatus including the element.

Through the above description of the implementations, a person skilled in the art may clearly know that the foregoing embodiment method may be implemented by means of software with necessary universal hardware platforms, and may also be implemented by means of hardware. However, the former is the optimal implementation in many circumstances. Based on this understanding, the technical solutions of the present application or the part contributing to the related art may be essentially embodied in a form of software products. The computer software product is stored in a storage medium (such as read-only memory/random access memory (ROM/RAM), magnetic disks, optical disks, etc.) including a plurality of instructions for making a terminal device (which may be a mobile phone, a computer, a resource server, an air conditioner, or a network device, etc.) execute the methods described in each embodiment of the present application.

The embodiments of the present application are described above in conjunction with the drawings, but the present application is not limited to the above specific embodiments. The above specific embodiments are only illustrative and not restrictive. Various forms could be made by a person skilled in the art without departing from the purpose of the present application and the protection scope claimed by the claims under the inspiration of the present application should fall within the protection scope of the present application.

A person skilled in the art may realize that units and algorithm steps of various examples described in the embodiments disclosed herein may be implemented by electronic hardware or a combination of computer software and the electronic hardware. Whether these functions are executed with hardware or software depend on the specific application and designed constraint conditions of the technical solution. Professional technicians may use different methods to implement the described functions for each specific application, but such implementation should not be considered beyond the scope of the present disclosure.

A person skilled in the art may clearly learn about that for the convenience and brevity of description, the specific working process of the above systems, apparatuses and units may refer to the corresponding processes in the foregoing method embodiments, which is not repeated here.

In the embodiments provided in the present disclosure, it should be understood that the disclosed apparatuses and methods may be implemented in other ways. For example, the apparatus embodiments described above are merely illustrative. For example, the division of the units is only a logical function division, and there may be other divisions in actual implementation, for example, multiple units or components may be combined or integrated into another system, or some features may be ignored or not implemented. In addition, the displayed or discussed mutual coupling or direct coupling or communication connection may be indirect coupling or communication connection through interfaces, apparatuses or units, and may be in electrical, mechanical or other forms.

The units described as separate parts may or may not be physically separated, and components displayed as units may or may not be physical units, namely, may be located in one position, or may be distributed on a plurality of network units. Some or all of the units may be selected according to actual needs to achieve the objectives of the solutions of the embodiments.

In addition, functional units in the embodiments of the present application may be integrated into one processing unit, or each of the units may be physically separated, or two or more units may be integrated into one unit.

If the integrated unit is implemented in the form of a software functional unit and sold or used as an independent product, it may be stored in a non-transitory computer-readable storage medium. Based on this understanding, the technical solutions of the present application or the part contributing to the related art or part of the technical solutions may be essentially embodied in a form of software products. The computer software product may be stored in a computer readable storage medium including a plurality of instructions for making a computer device (which may be a personal computer, a server, or a network device, etc.) execute all or some steps of the methods described in each embodiment of the present application. The foregoing non-volatile readable storage medium includes media capable of storing program codes, such as a USB flash drive, a portable hard disk, a read-only memory (ROM), a random access memory (RAM), a magnetic disk or a compact disk, etc.

The above are only specific implementations of the present application but the protection scope of the present application is not limited thereto. Any simple variations or replacements made by the technical skilled familiar with the related art within the technical scope disclosed by the present application shall be covered by the protection scope of the present application. Therefore, the protection scope of the present application should be subjected to the protection scope defined by the claims.

1. A buoyancy tray, configured to place a server into a cabinet containing immersion coolant, comprising:
a tray body, wherein a server slot configured to load the server is disposed at one end of the tray body, handles are disposed at two sides of the one end of the tray body, and two sides of the tray body are provided with first recessed slide tracks matched with first protruding slide tracks inside the cabinet; and
a buoyancy component, wherein the buoyancy component is disposed on the tray body, and an inside of the buoyancy component is a closed hollow structure, and the buoyancy component is configured to provide buoyancy for the tray body-;
wherein latch slots are disposed at preset intervals on each of the first protruding slide tracks, and each of the first recessed slide tracks is provided with latches matched with the latch slots;
each of the first recessed slide tracks is also provided with a fixed shaft and a pull rod, and each of the handles of the tray body is provided with a pull ring;
each of the latches is sleeved on the fixed shaft, one end of the pull ring is connected to one end of the pull rod in each of the first recessed slide tracks, the other end of the pull rod is provided with a beveled clamping block, a clamping slot is disposed at one end of each of the latches close to the pull rod, the beveled clamping block is movably clamped into the clamping slot, a clamping tooth matched with the latch slot is disposed at one end of the each of the latches away from the pull rod, and an elastic component is disposed between the clamping tooth and each of the first recessed slide tracks;
in response to the pull ring being not pulled, the clamping tooth is embedded into the latch slot under an action of an elastic force of the elastic component; and
in response to the pull ring being pulled, the beveled clamping block of the pull rod is driven to move towards the handle, the latch rotates around the fixed shaft, one end of the latch provided with the clamping slot moves away from the tray body, the clamping tooth moves towards the tray body, the elastic component is compressed, and the clamping tooth is separated from the latch slot.

2. The buoyancy tray according to claim 1, wherein the buoyancy component comprises buoyancy air holders, the buoyancy air holders are disposed at two sides of the tray body, and each of the first recessed slide tracks is disposed at one end of each of the buoyancy air holders away from the tray body.

3. The buoyancy tray according to claim 1, wherein the buoyancy component comprises air holder filling blocks, and the air holder filling blocks are disposed at a bottom of the server slot.

4. The buoyancy tray according to claim 3, wherein the air holder filling blocks are distributed in a spaced array in the server slot.

5. The buoyancy tray according to claim 2, wherein each of the buoyancy air holders is provided with scale marks along a length direction.

6. The buoyancy tray according to claim 5, wherein the scale marks are uniformly distributed at intervals along the length direction.

7. (canceled)

8. The buoyancy tray according to claim 1, wherein each of the first protruding slide tracks is formed by a plurality of protruding slide blocks that are distributed at intervals.

9. The buoyancy tray according to claim 8, wherein the latch slots are disposed on the protruding slide blocks.

10. (canceled)

11. The buoyancy tray according to claim 1, wherein the fixed shaft is located at one end within each of the first recessed slide tracks away from the handle.

12. The buoyancy tray according to claim 1, wherein the elastic component is a spring or an elastic sheet.

13. (canceled)

14. The buoyancy tray according to claim 1, wherein the server comprises a rack formed by a chassis base and a top cover, handles are disposed at two sides of one end of the chassis base, and air holder filling blocks are disposed at the other end of the chassis base.

15. The buoyancy tray according to claim 14, wherein each of two sides of the chassis base is provided with a second protruding slide track, and second recessed slide tracks matched with the second protruding slide tracks are disposed in the server slot.

16. The buoyancy tray according to claim 14, wherein locking nuts are disposed at two sides of the one end of the tray body, and locking screws matched with the locking nuts are disposed at two sides of one end of the chassis base.

17. The buoyancy tray according to claim 16, wherein the air holder filling blocks are distributed in a spaced array at the other end of the chassis base.

18. The buoyancy tray according to claim 14, wherein a bottom of the tray body is a hollowed structure.

19. A server, comprising the buoyancy tray according to claim 1.

20. A server cluster, comprising the cabinet containing the immersion coolant and the server according to claim 19.

21. The buoyancy tray according to claim 14, wherein a bottom of the chassis base and the top cover are both hollowed structures.

22. The buoyancy tray according to claim 14, wherein the air holder filling blocks are cube air holder filling blocks.

23. The buoyancy tray according to claim 2, wherein the buoyancy air holders are cuboid buoyancy air holders.
